(19) United States
(12) Patent Application Publication
(10) Pub. No.: US 2008/0233762 A1
(43) Pub. Date: Sep. 25, 2008

(54) METHOD OF MANUFACTURING SEMICONDUCTOR DEVICE

(75) Inventor: Kwon HONG, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/950,220

(22) Filed: Dec. 4, 2007

(30) Foreign Application Priority Data
Mar. 23, 2007 (KR) 10-2007-0028574

(51) Int. Cl. H01L 21/469

(52) U.S. Cl. 438/763; 257/E21.487

(57) ABSTRACT

A method of manufacturing a semiconductor device includes forming a high dielectric insulating layer. An amorphous high dielectric insulating layer having a high density is formed by using a precursor which can be deposited through the atomic layer deposition method at a temperature above 400° C. A resulting insulating exhibits a reduced crystallization during a subsequent annealing process. The capacitance equivalent thickness (CET) characteristic and the leakage current characteristic are improved.

### CROSS-REFERENCE TO RELATED APPLICATIONS

This application claims priority from Korean Patent Application No. 2007-28574, filed on Mar. 23, 2007, the contents of which are incorporated herein by reference in its entirety.

### BACKGROUND OF THE INVENTION

The present invention relates to a method of manufacturing a semiconductor device. In particular, the present invention relates to a method of manufacturing a semiconductor device capable of improving the capacitance equivalent thickness (CET) characteristic and the leakage current characteristic.

In general, a non-volatile memory device retains its stored data even after the electric power is turned off. In a non-volatile flash memory device, a unit cell of the flash memory device is formed by sequentially stacking a tunnel insulating layer, a floating gate, a dielectric layer and a control gate on an active area of a semiconductor substrate. A voltage applied to the gate electrode is coupled to the floating gate so that the memory device stores the data. Accordingly, in order to store the data in a short period of time and with a low program voltage, a ratio between a voltage applied to the control gate and a voltage induced at the floating gate (i.e., a coupling ratio) must be high. Here, the coupling ratio can be expressed as a ratio between a capacitance of the dielectric layer and a sum of the capacitance of the tunnel oxide layer and the dielectric layer.

In the conventional flash memory device, a SiO₂/Si₃N₄/SiO₂ (oxide-nitride-oxide or ONO) structure has been used typically as a dielectric layer for spacing the floating gate from the control gate. Recently, as a thickness of the dielectric layer is decreased due to high integration of the device, a leakage current caused by tunneling is increased, and so the reliability of the device is lowered.

To solve the above mentioned problem, using novel material capable of substituting for the dielectric layer, development of a high dielectric insulating layer (high-k) which is a metallic oxide material having a dielectric constant which is higher than that of SiO₂ or Si₃N₄ has been proposed. That is, if the dielectric constant is high, a thickness required for obtaining the same capacitance can be decreased, and so it is possible to improve a leakage current characteristic in an uniform equivalent oxide thickness (EOT) than in SiO₂.

However, it is difficult to adjust the coupling ratio when the entire dielectric structure is substituted with the single layer high dielectric material (high-k), and so a study for substituting only a nitride layer in a conventional ONO structure with the high dielectric material (high-k) has been actively researched. Recently, the dielectric layer having an OKO structure (wherein, “K” indicates a high dielectric material (high-k)) has been introduced. The OKO includes a high dielectric material such as a hafnium oxide (HfO₂) layer formed by using Tetrakis (ethylmethylamino) hafnium {Hf[N(CH₃)C₂H₅]₄, Hf(NEtMe)₄; hereinafter, referred to as “TEMAH”} as a precursor and zirconium oxide (ZrO₂) layer formed by using Tetrakis (ethylmethylamino) zirconium {Zr[N(CH₃)C₂H₅]₄, Zr(NEtMe)₄; hereinafter, referred to as “TEMAZ”} as a precursor, which are amide precursors. At this time, HfO₂(ε=25) or ZrO₂(ε=25) having a relatively high dielectric constant can secure an excellent capacitance, but has a low yield electric field strength. Accordingly, HfO₂ or ZrO₂ is vulnerable to a repeated electrical impact so that a durability of the capacitor is lowered. In order to overcome the above problem, a stack structure of HfO₂/Al₂0₃ layer or ZrO₂/Al₂O₃ layer formed by using Al₂O₃ which has an excellent leakage current characteristic has been proposed. In this case, it is easy to adjust a thickness and a composition of high dielectric material (high-k), and high dielectric material is deposited in a laminate shape which is in an amorphous state through an atomic layer deposition (ALD) method having an excellent step coverage property. Conventional Hf precursors or Zr precursors such as TEMAH and TEMAZ has a low dissolving temperature and a low vapor pressure at a high temperature, and so Hf or Zr is deposited at a low temperature around 300° C.

However, if high dielectric material (high-k) is deposited at a low temperature in the laminate manner through an atomic layer deposition method, a high dielectric material becomes a mixture or composite shape in a subsequent high temperature annealing process. An amorphous laminate is changed into a crystalline structure so that current is leaked through a grain boundary path. Accordingly, the high dielectric material does not satisfy a leakage current characteristic in a high electric field.

### SUMMARY OF THE INVENTION

The present invention relates to a method of manufacturing a semiconductor device capable of forming an amorphous high dielectric insulating layer having a high density by using a precursor which can be deposited at a temperature above 400° C. through an atomic layer deposition (ALD) method to improve a capacitance equivalent thickness (CET) characteristic and a leakage current characteristic.

### BRIEF DESCRIPTION OF THE DRAWINGS

FIG. 1A to FIG. 1C are sectional views of a flash memory device for illustrating a method of manufacturing a flash memory device according to one embodiment of the present invention;

FIG. 2 is a graph showing a dissolving temperature of a precursor applied to the present invention and a remaining amount of a precursor according to a dissolving temperature;

FIG. 3 is a graph showing vapor pressure relative to temperature of a precursor applied to the present invention;

FIG. 4 is a view for illustrating an atomic layer deposition (ALD) method employed for forming a single-layered high dielectric insulating layer according to the present invention;

FIG. 5 is a view for illustrating an atomic layer deposition method employed for forming a lamination-type high dielectric insulating layer according to the present invention;

FIG. 6 is a view for illustrating an atomic layer deposition method employed for forming a nano-mixed type high dielectric insulating layer according to the present invention; and

FIG. 7 is a graph showing a capacitance equivalent thickness (CET) characteristic and a leakage current characteristic of a high dielectric insulating layer according to the present invention.

### DESCRIPTION OF SPECIFIC EMBODIMENTS

Hereinafter, the embodiments of the present invention will be explained in more detail with reference to the accompanying drawings. However, the present invention is not limited to the embodiment disclosed below, but can be embodied in various shapes.

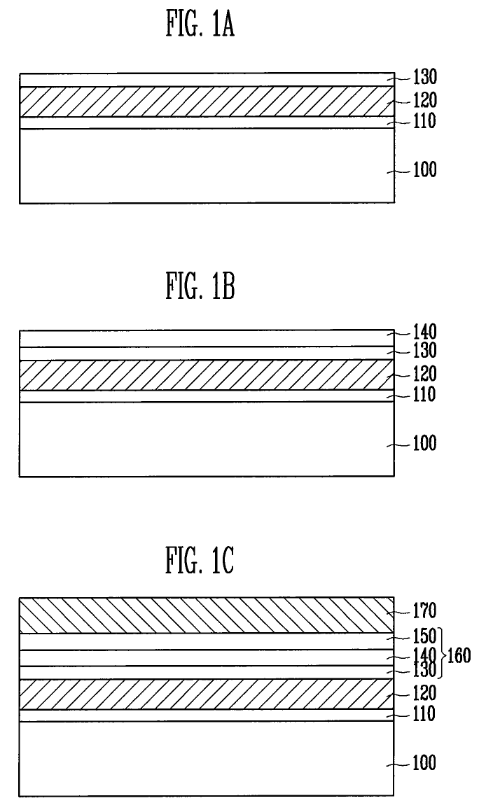

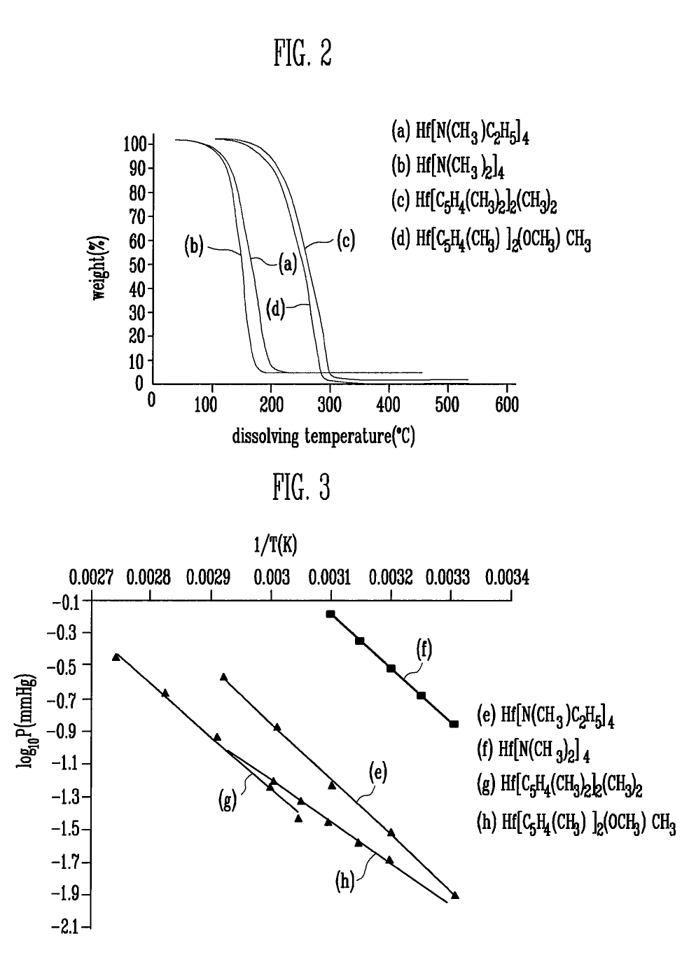

FIG. 1A to FIG. 1C are sectional views of a flash memory device for illustrating a method of manufacturing a flash memory device according to one embodiment of the present invention.

Referring to FIG. 1A, a semiconductor substrate 100 on which a lower layer comprising a first insulating layer 110, a first conductive layer 120 and a second insulating layer 130 is formed is provided. Here, in order to utilize the first insulating layer as a tunnel insulating layer in a NAND flash memory and an underlying inter-insulating layer in a process for manufacturing a capacitor, the first insulating layer 110 can be formed of a silicon oxide (SiO₂) layer. In this case, the first insulating layer 110 can be formed through an oxidation process or a chemical vapor deposition (CVD) method (e.g., a low pressure chemical vapor deposition method).

The first conductive layer 120 is used as a floating gate of a NAND flash device or an underlying electrode of a capacitor, the first conductive layer can be formed of a doped polysilicon layer, a metal layer or a stack layer comprising of the two. The first conductive layer 120 may be formed of a doped polysilicon layer. The first conductive layer 120 may be formed through a chemical vapor deposition method. The first conductive layer may be formed with a thickness of 500 Å to 2,000 Å by means of a low pressure chemical vapor deposition (LPCVD) method. At this time, the first conductive layer 120 is patterned in parallel with an isolation structure (not shown).

The second conductive layer 130 is used as an underlying oxide layer of a dielectric layer between a floating gate and a control gate of a NAND flash device and as an inter-insulating layer between an underlying electrode and an overlying electrode of a capacitor in a process for manufacturing a capacitor. The second conductive layer can be formed of a high temperature oxide (HTO) layer. In this case, the second conductive layer can be formed with a thickness of 10 Å to 50 Å by means of a chemical vapor deposition method (e.g., a low pressure chemical vapor deposition (LPCVD) method).

Referring to FIG. 1B, a high dielectric insulating layer 140 (high-k) is formed on the second insulating layer 130. The high dielectric insulating layer 140 according to the present embodiment is formed through an atomic layer deposition (ALD) method at a temperature of 400 to 500° C., or at a temperature range of 450 to 500° C. using a precursor selected from materials expressed by chemical formula 1 to chemical formula 6 shown below. The high dielectric insulating structure can be formed of three thickness controlled layers described below by adjusting the unit cycle of the atomic layer deposition (ALD) method. The deposition temperature of the new precursors of the present embodiment for hafnium (Hf) or zirconium (Zr) expressed by the chemical formula 1 to chemical formula 6 will be described later.

First, the high dielectric insulating layer 140 is formed of an amorphous hafnium oxide (HfO₂) layer or an amorphous zirconium oxide (ZrO₂) layer. At this time, if the high dielectric insulating layer 140 is formed of the hafnium oxide (HfO₂) layer, hafnium oxide (HfO₂) layer is formed in an amorphous state through the atomic layer deposition (ALD) method at a temperature of 400 to 500° C. using a precursor selected from Hf[C₅H₄(CH₃)]₂(CH₃)₂ expressed by the chemical formula 1, Hf[C₅H₄(CH₃)]₂(OCH₃)CH₃ expressed by the chemical formula 2, and Hf[C₅H₄(CH₂CH₃)][N(CH₃)(CH₂CH₃)]₃ expressed by the chemical formula 3. The high dielectric insulating layer 140 formed of the hafnium oxide (HfO₂) layer may also be formed in an amorphous state through the atomic layer deposition method at a temperature of 450 to 500° C. using a precursor selected from materials expressed by the chemical formula 1 to the chemical formula 3 shown below. In one implementation, the hafnium oxide (HfO₂) layer has a thickness of 40 to 500 Å.

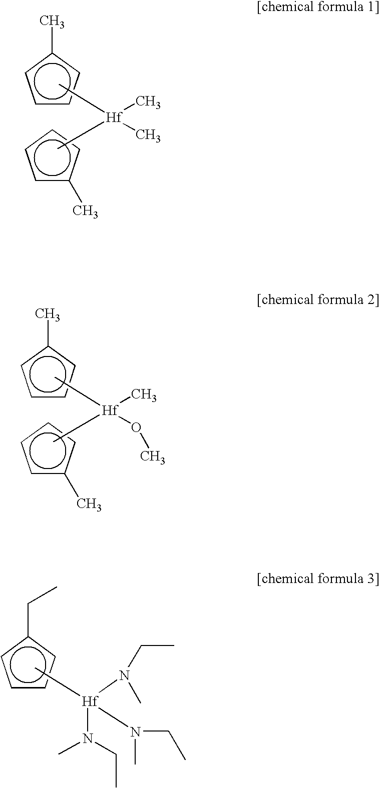

Next, if the high dielectric insulating layer 140 is formed of the zirconium oxide (ZrO₂) layer, the zirconium oxide (ZrO₂) layer is formed in an amorphous state through the atomic layer deposition (ALD) method at a temperature of 400 to 500° C. using a precursor selected from Zr[C₅H₄(CH₃)]₂(CH₃)₂ expressed by the chemical formula 4, Zr[C₅H₄(CH₃)]₂(OCH₃)CH₃ expressed by the chemical formula 5, and Zr[C₅H₄(CH₂CH₃)][N(CH₃)(CH₂CH₃)]₃ expressed by the chemical formula 6. The high dielectric insulating layer 140 formed of the zirconium oxide (ZrO₂) layer may also be formed in an amorphous state through the atomic layer deposition method at a temperature of 450 to 500° C. using a precursor selected from materials expressed by the chemical formula 4 to the chemical formula 6 shown below. In one implementation, the zirconium oxide (ZrO₂) layer has a thickness of 40 to 500 Å.

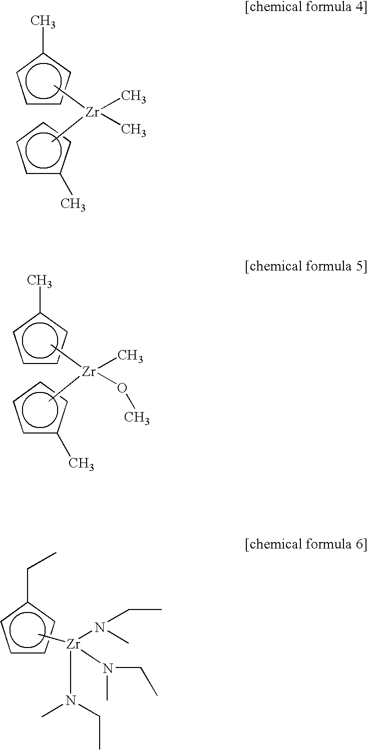

FIG. 2 is a graph showing dissolving temperature of a precursor applied to the present invention versus the remaining amount of precursor, and FIG. 3 is a graph showing vapor pressure relative to a temperature of the precursor applied to the present embodiment.

Referring to FIG. 2, the hafnium (Hf) precursor expressed by the chemical formula 1 and the chemical formula 2 such as the line (c)-Hf[C₅H₄(CH₃)]₂(CH₃)₂, and the line (d)-Hf[C₅H₄(CH₃)]₂(OCH₃)CH₃, has a dissolving temperature that is about 100° C. more than that of a conventional amide precursor which is the (a)-Hf[N(CH₃)C₂H₅]₄, and the line (b)-Hf[N(CH₃)₂]₄. The amount remaining as dissolving temperature increases is also lower than that of the conventional amide precursor. Accordingly, the hafnium (Hf) precursor expressed by the chemical formula 1 and the chemical formula 2 according to the present embodiment can be deposited at a temperature above 400° C.

Here, the lines (a) through (d) indicate the hafnium (Hf) precursors, the line (a) indicates Tetrakis(ethylmethylamino)hafnium, Hf[N(CH₃)C₂H₅]₄, Hf(NEtMe)₄ (hereinafter, referred to as ‘TEMAH’), the line (b) indicates Tetrakis(dimethylamino)hafnium, Hf[N(CH₃)₂]₄, Hf(NMe₂)₄ (hereinafter, referred to as “TDMAH'”), the line (c) indicates Hf[C₅H₄(CH₃)]₂(CH₃)₂, and the line (d) indicates Hf[C₅H₄(CH₃)]₂(OCH₃)CH₃.

On the other hand, although not shown in the drawings, like the hafnium (Hf) precursor of Hf[C₅H₄(CH₃)]₂(CH₃)₂ and Hf[C₅H₄(CH₃)]₂(OCH₃) CH₃ shown in the line (c) and the line (d) in FIG. 2, the hafnium (Hf) precursor or the zirconium (Zr) precursor expressed by the chemical formula 3 to the chemical formula 6 has a dissolving temperature that is about 100° C. more than that of a conventional amide precursor such as TEMAH and TDMAH and an amount remaining as dissolving temperature increases is lower than that of the conventional amide precursor. Accordingly, the hafnium (Hf) precursor or the zirconium (Zr) precursor expressed by the chemical formula 3 to the chemical formula 6 according to the present embodiment can also be deposited at a temperature above 400° C.

Referring to FIG. 3, like the line (g)-Hf[C₅H₄(CH₃)]₂(CH₃)₂, the line (h)-Hf[C₅H₄(CH₃)]₂(OCH₃)CH₃, the hafnium (Hf) precursor expressed by the chemical formula 1 and the chemical formula 2 has a vapor pressure at a high temperature that is higher than that of a conventional amide precursor which is the line (e)-Hf[N(CH₃)C₂H₅]₄, the line (f)-Hf[N(CH₃)₂]₄. Due to the above characteristic, the hafnium (Hf) precursor expressed by the chemical formula 1 and the chemical formula 2 applied to the present embodiment is highly volatile so that the hafnium (Hf) precursor is deposited well at a high temperature. Accordingly, the hafnium (Hf) precursor may be deposited at a temperature above 400° C.

Although not shown in the drawings, like the hafnium (Hf) precursor of Hf[C₅H₄(CH₃)]₂(CH₃)₂ and Hf[C₅H₄(CH₃)]₂(OCH₃)CH₃ shown in the line (g) and the line (h) in FIG. 3, the hafnium (Hf) precursor or the zirconium (Zr) precursor expressed by the chemical formula 3 to the chemical formula 6 has a vapor pressure at a high temperature that is higher than that of a conventional amide precursor such as TEMAH and TDMAH. Accordingly, the hafnium (Hf) precursor or the zirconium (Zr) precursor expressed by the chemical formula 3 to the chemical formula 6 according to the present embodiment is highly volatile so that the hafnium (Hf) precursor or the zirconium (Zr) precursor is deposited well at a high temperature. Consequently, the hafnium (Hf) precursor or the zirconium (Zr) precursor may be deposited at a temperature above 400° C.

As described above, since the hafnium (Hf) precursor or the zirconium (Zr) precursor expressed by the chemical formula 3 to the chemical formula 6 has a vapor pressure at a high temperature that is higher than that of a conventional amide precursor such as TEMAH and TDMAH and a dissolving temperature that is about 100° C. more than that of a conventional amide precursor, if a hafnium oxide (HfO₂) layer or zirconium oxide (ZrO₂) layer is formed by using the hafnium (Hf) precursor or the zirconium (Zr) precursor, hafnium oxide (HfO₂) or zirconium oxide (ZrO₂) can be deposited at a temperature above 400° C. At this time, in order to increase a density of the amorphous high dielectric insulating layer, the hafnium oxide (HfO₂) layer or zirconium oxide (ZrO₂) layer may be formed at a high temperature of 450 to 500° C. using any one precursor selected from materials expressed by the chemical formula 4 to the chemical formula 6, each having a high dissolving temperature and a high vapor pressure at a high temperature.

In the general atomic layer deposition (ALD) method, a metal precursor source and reaction gas are not supplied simultaneously, one of the metal precursor source and the reaction gas is supplied first, a purge process is performed, and then the other one is supplied, and so an absorption/desorption reaction is generated.

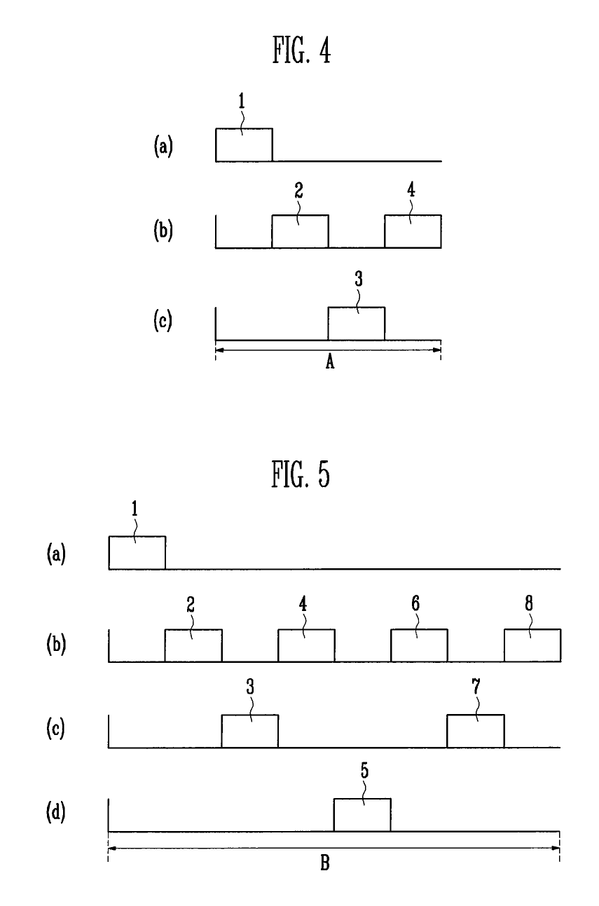

FIG. 4 is a view for illustrating the atomic layer deposition (ALD) method employed for forming a single-layered high dielectric insulating layer according to the present embodiment. The atomic layer deposition (ALD) method for forming the first type high dielectric insulating layer according to the present embodiment is briefly illustrated with reference to FIG. 4.

Referring to FIG. 4, the atomic layer deposition (ALD) method employed for forming a single-layered high dielectric insulating layer according to the present embodiment includes the step (a) for supplying metal precursor source, the step (b) for purging and the step (c) for supplying reaction gas. Each rectangle represents a step performed. That is, any one of materials expressed by the chemical formula 1 to the chemical formula 6 may be supplied as a metal precursor source (step 1). A purge process is performed (step 2). Reaction gas/plasms (e.g., H₂O, O₃ gas or O₂ plasma) is supplied at a wafer temperature of 300 to 600° C. (step 3). A purge process is performed again (step 4). These steps 1-4 are defined as “unit cycle (A)”, where the unit cycle A is repeatedly performed so as to form a layer of predetermined thickness. In one implementation, the high dielectric insulating layer having a total thickness of 40 to 500 Å is formed by varying the number of the unit cycle (A) performed. Here, nitrogen (N₂) and/or argon (Ar) are used as a purge gas to inhibit a chemical vapor deposition (CVD) reaction from being performed, and so an amorphous hafnium oxide (HfO₂) layer and an amorphous zirconium oxide (ZrO₂) layer having an excellent layer quality and a high density are formed.

As described above, the high dielectric insulating layer 140 having a single layer of the hafnium oxide (HfO₂) layer or the zirconium oxide (ZrO₂) layer according to the present embodiment is formed through the atomic layer deposition method at a temperature of 400 to 500° C., or at a temperature range of 450 to 500° C. using a precursor selected from materials expressed by the chemical formula 1 to the chemical formula 6 having a high dissolving temperature characteristic and a high vapor pressure characteristic at a high temperature, and so the high dielectric insulating layer having a high density is formed in an amorphous state.

The high dielectric insulating layer 140 formed as described above shows less tendency to crystallize during a subsequent annealing process performed at a temperature of 700 to 1,000° C., than the conventional high dielectric insulating layer formed at a temperature of approximately 300° C. Consequently, a grain boundary path of the high dielectric insulating layer 140 would be less, thereby enhancing the CET characteristic and a leakage current characteristic.

Second, by stacking alternatively amorphous HfO₂/Al₂O₃ layers or amorphous ZrO₂/Al₂O₃ layers, the high dielectric insulating layer 140 is stacked in the form of a laminate to which the layer-by-layer concept is applied.

In the present embodiment, each of the HfO₂ layer, ZrO₂ layer and Al₂O₃ layer in the high dielectric insulating layer 140 is formed with a thickness of 10 or 30 Å. When a stack structure of the HfO₂/Al₂O₃ layers or ZrO₂/Al₂O₃ layers is defined as “one film”, at least two films are formed by stacking the structure of HfO₂/Al₂O₃ layers or ZrO₂/Al₂O₃ layers to form a multi filmed laminate. However, the multi filmed laminate is formed such that the total thickness of the high insulating dielectric 140 is 40 to 500 Å.

More concretely, if the high dielectric insulating layer 140 in the form of the multi-filmed laminate is formed by stacking alternately the HfO₂ layer and the Al₂O₃ layer, the HfO₂ layer is formed with a thickness of 10 to 30 Å through the atomic layer deposition method at a temperature of 400 to 500° C., or a more narrow temperature range of 450 to 500° C. using a precursor selected from Hf[C₅H₄(CH₃)]₂(CH₃)₂ expressed by the chemical formula 1, Hf[C₅H₄(CH₃)]₂(OCH₃)CH₃ expressed by the chemical formula 2, and Hf[C₅H₄(CH₂CH₃)][N(CH₃)(CH₂CH₃)]₃ expressed by the chemical formula 3 having a high dissolving temperature and a high vapor pressure at a high temperature, and the Al₂O₃ layer is formed with a thickness of 10 to 30 Å through the atomic layer deposition method at a temperature of 400 or 500° C., or at a temperature range of 450 to 500° C. using a trimethyl aluminum (Al(CH₃)₃ (hereinafter, referred to as “TMA”) precursor. With this, the high dielectric insulating layer 140 is formed at a high temperature of 400 to 500° C., and so the high dielectric insulating layer has a laminate shape having a stack structure with the amorphous HfO₂/Al₂O₃ layers having a high density.

Next, in a case where the high dielectric insulating layer 140, in the form of the multi-filmed laminate, is formed by alternately stacking the ZrO₂ layer and the Al₂O₃ layer, the ZrO₂ layer is formed with a thickness of 10 to 30 Å through the atomic layer deposition method at a temperature of 400 or 500° C. using a precursor selected from Zr[C₅H₄(CH₃)]₂(CH₃)₂ expressed by the chemical formula 4, Zr[C₅H₄(CH₃)]₂(OCH₃)CH₃ expressed by the chemical formula 5 and Zr[C₅H₄(CH₂CH₃)][N(CH₃)(CH₂CH₃)]₃ expressed by the chemical formula 6 having a high dissolving temperature and a high vapor pressure at a high temperature, and the Al₂O₃ layer is formed with a thickness of 10 to 30 Å through the atomic layer deposition method at a temperature of 400 or 500° C. using the TMA precursor. With this, the high dielectric insulating layer 140 is formed at a high temperature of 400 to 500° C., and so the high dielectric insulating layer has a laminate form with the stack structure of the amorphous ZrO₂/Al₂O₃ layers having a high density.

In a case where the HfO₂ layer or the ZrO₂ layer is formed through the atomic layer deposition method at a temperature of 400 to 500° C., or at a temperature of 450 to 500° C. using any one precursor selected from materials expressed by the chemical formula 1 to the chemical formula 6 according to the present embodiment having a high dissolving temperature and a high vapor pressure at a high temperature, since it is possible to form the Al₂O₃ layer at a high temperature of 400° C. or more using the TMA having a high volatility as the precursor, an electrical characteristic of the thin layer can be enhanced by forming the high dielectric insulating layer in a laminate form consisting of HfO₂ layers and Al₂O₃ layers or ZrO₂ layers and Al₂O₃ layers.

On the other hand, the high dielectric insulating layer 140 can be formed in the form of the multi-filmed laminate in which the stack structures of the Al₂O₃/HfO₂ layers or the Al₂O₃/ZrO₂ layers, which are the reversed structures of the HfO₂/Al₂O₃ layers or the ZrO₂/Al₂O₃ layers, are alternately stacked.

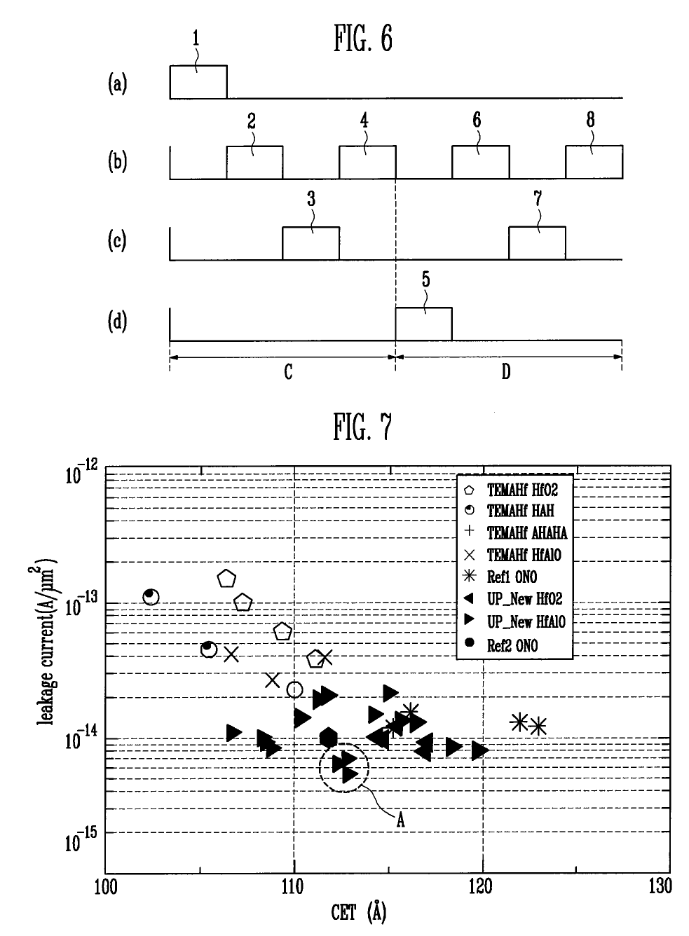

FIG. 5 is a view for illustrating the atomic layer deposition (ALD) method employed for forming a laminate-type high dielectric insulating layer according to the present embodiment. The atomic layer deposition (ALD) method for forming the second type high dielectric insulating layer according to the present embodiment is briefly illustrated with reference to FIG. 5.

Referring to FIG. 5, the atomic layer deposition (ALD) method employed for forming the laminate-type high dielectric insulating layer according to the present embodiment includes the step (a) for supplying a first metal precursor source, the step (b) for purging, the step (c) for supplying a reaction gas and the step (d) for supplying a second metal precursor source. The first metal precursor source (e.g., any one of the materials expressed by the chemical formula 1 to the chemical formula 6) is supplied (step 1), a purge process is performed (step 2), H₂O, O₃ gas or O₂ plasma is supplied as a reaction gas at a wafer temperature of 300 to 600° C. (step 3), a purge process is then performed (step 4), TMA is supplied as a second metal precursor source (step 5), a purge process is performed (step 6), and H₂O, O₃ gas or O₂ plasma is supplied as a reaction gas at a wafer temperature of 300 to 600° C. (step 7), a purge process is then performed (step 8). Here, the steps 1 through 8 is defined as “unit cycle (B)”, the unit cycle B is repeatedly performed so as to form a e layer of desired thickness. At this time, the HfO₂ layer, ZrO₂ layer and Al₂O₃ layer are formed with a thickness of 10 or 30 Å by adjusting the number of unit cycles (B) performed. The high dielectric insulating layer is formed to have a total thickness of 40 to 500 Å. Here, nitrogen (N₂) and argon (Ar) are used as a purge gas to inhibit a chemical vapor deposition (CVD) reaction from being performed, and so the amorphous hafnium oxide (HfO₂) layer and the amorphous zirconium oxide (ZrO₂) layer having an excellent layer quality and a high density are formed. On the other hand, the step for supplying a first metal precursor source can be performed after the step for supplying a second metal precursor source is performed. At this time, the high dielectric insulating layer 140 can be formed in the form of the multi-filmed laminate in which the stack structures of the Al₂O₃/HfO₂ layers or the Al₂O₃/ZrO₂ layers, which are the reversed structures of the HfO₂/Al₂O₃ layers or the ZrO₂/Al₂O₃ layers, are alternatively stacked.

The high dielectric insulating layer 140 is formed in the form of the multi-filmed laminate in which the HfO₂/Al₂O₃ layers or ZrO₂/Al₂O₃ layers are alternatively stacked. The layer 140 comprises the amorphous HfO₂ layer or ZrO₂ layer having a high density formed through the atomic layer deposition method at the temperature of 400 to 500° C. using a precursor selected from materials expressed by the chemical formula 1 to the chemical formula 6 having a high dissolving temperature and a high vapor pressure at a high temperature. As a result, although a subsequent-annealing process is performed at a high temperature of 700 to 1,000° C., crystallization in the high dielectric insulating layer 140 is reduced compared to the high dielectric insulating layer formed at a temperature of approximately 300° C., and so a grain boundary path can be decreased to lower the CET and to reduce leakage current.

The high dielectric insulating layer 140 is not formed by stacking the HfO₂ layer and Al₂O₃ layer or the ZrO₂ layer and Al₂O₃ layer in the layer by layer manner, but formed of an amorphous hafnium-aluminum oxide (HFAlO) layer or zirconium-aluminum oxide (ZrAlO) layer which are nano-mixed.

If the high dielectric insulating layer 140 is formed of the HfAlO layer, the amorphous HfO₂ layer formed through the atomic layer deposition method at the temperature of 400 to 500° C., or a temperature range of 450 to 500° C. using a precursor selected from Hf[C₅H₄(CH₃)]₂(CH₃)₂ expressed by the chemical formula 1, Hf[C₅H₄(CH₃)]₂(OCH₃)CH₃ expressed by the chemical formula 2, and Hf[C₅H₄(CH₂CH₃)][N(CH₃)(CH₂CH₃)]₃ expressed by the chemical formula 3 having a high dissolving temperature and a high vapor pressure at a high temperature and the amorphous Al₂O₃ layer formed through the atomic layer deposition method at the temperature of 400 to 500° C., or at a temperature range of 450 to 500° C. using a TMA precursor are alternately stacked. However, to increase the nano-mixed effect of the HfO₂ layer and Al₂O₃ layer, the HfO₂ layer and the Al₂O₃ layer formed through the atomic layer deposition method are formed with a thin thickness below 10 Å (0.1 Å to 9.9 Å) per unit cycle. Here, a thickness of 0.1 Å to 9.9 Å of the HfO₂ layer and the Al₂O₃ layer is obtained when each layer is non-continuously formed. If the layer is formed with a thickness above 10 Å, the layer has an independent structure in the form of a continuous layer, and so the high dielectric insulating layer has a structure in which HfO₂ layer and the Al₂O₃ layer are stacked in the form of a layer by layer shape. At this time, the total thickness of the high dielectric insulating layer is 40 to 500 Å.

In particular, rather than the layer by layer concept, to obtain the nano-mixed structure in which the HfO₂ layer and Al₂O₃ layer are mixed, a composition ratio between hafnium (Hf) and aluminum (Al) is adjusted by adjusting the number of unit cycles for each of these layers. For the above, “m” and “n” which are the number of the unit cycle are adjusted in the “m” cycle (supplying Hf source/purge/supplying reaction gas) and the “n” cycle (supplying Al source/purge/supplying reaction gas).

At this time, in order to secure a sufficient capacitance, the HfAlO layer is formed such that a composition ratio of Hf having a high dielectric constant (ε=25) is larger than that of Al having a low dielectric constant (ε=9), the HfAlO layer may be formed such that a composition ratio between Hf:Al becomes 2:1 to 30:1, e.g., the HfAlO layer is formed such that a composition ratio between Hf:Al becomes 24:1.

Next, if the high dielectric insulating layer 140 is formed of a ZrAlO layer, the amorphous ZrO₂ layer formed through the atomic layer deposition method at a temperature of 400 to 500° C., or at a temperature range of 450 to 500° C. using a precursor selected from Zr[C₅H₄(CH₃)]₂(CH₃)₂ expressed by the chemical formula 4, Zr[C₅H₄(CH₃)]₂(OCH₃)CH₃ expressed by the chemical formula 5 and Zr[C₅H₄(CH₂CH₃)][N(CH₃)(CH₂CH₃)]₃ expressed by the chemical formula 6 having a high dissolving temperature and a high vapor pressure at a high temperature and the amorphous Al₂O₃ layer formed through the atomic layer deposition method at a temperature of 400 to 500° C., or at a temperature range of 450 to 500° C. using the TMA precursor are alternately stacked. However, to increase the nano-mixed effect of the ZrO₂ layer and the Al₂O₃ layer, the ZrO₂ layer and Al₂O₃ layer to be formed through the atomic layer deposition method are formed with a thickness less than 10 Å (0.1 Å to 9.9 Å) per each cycle.

In particular, for the nano-mixed structure in which the ZrO₂ layer and the Al₂O₃ layer are mixed, the number of unit cycles by which each of these layers is formed is modified to adjust a composition ratio between Zr and Al. For the above, “m” and “n”, which are the number of the unit cycles, are adjusted in the “m” cycle (supplying Zr source/purge/supplying reaction gas) and the “n” cycle (supplying Al source/purge/supplying reaction gas). At this time, in order to secure a sufficient capacitance, the ZrAlO layer is formed such that a composition ratio of Zr having a high dielectric constant (ε=25) is larger than that of Al having a low dielectric constant (ε=9), the ZrAlO layer may be formed such that a composition ratio between Zr:Al becomes 2:1 to 30:1 e.g., ZrAlO layer is formed such that a composition ratio between Zr:Al becomes 24:1.

If the HfO₂ layer or ZrO₂ layer is formed through the atomic layer deposition method at a temperature of 400 to 500° C., or at a temperature range of 450 to 500° C. using a precursor selected from material expressed by the chemical formulas 1 to 6 having a high dissolving temperature and a high vapor pressure at a high temperature according to the present embodiment, the Al₂O₃ layer can be formed at a temperature above 400° C., and so the electrical characteristic of the thin layer can be enhanced by forming the amorphous high dielectric insulating layer in which the HfO₂ layer or the ZrO₂ layer is mixed with the Al₂O₃ layer.

On the other hand, the nano-mixed type amorphous HfAlO layer or the ZrAlO layer can be formed through the amorphous thin layer in which the stack structures of the Al₂O₃/HfO₂ layers or the Al₂O₃/ZrO₂ layers, which are the reversed structures of the HfO₂/Al₂O₃ layers or the ZrO₂/Al₂O₃ layers, are alternately stacked.

FIG. 6 is a view for illustrating the atomic layer deposition method employed for forming the nano-mixed type high dielectric insulating layer according to the present embodiment. The atomic layer deposition method for forming the third type high dielectric insulating layer according to the present embodiment is briefly illustrated with reference to FIG. 6.

Referring to FIG. 6, the atomic layer deposition method employed for forming the nano-mixed type high dielectric insulating layer according to the present embodiment includes the step (a) for supplying first metal precursor source, the step (b) for purging, the step (c) for supplying reaction gas and the step (d) for supplying second metal precursor source. Any one of materials expressed by the chemical formula 1 to the chemical formula 6 is supplied as a first metal precursor source (step 1), a purge process is performed (step 2), H₂O, O₃ gas or O₂ plasma is supplied as a reaction gas at a wafer temperature of 300 to 600° C. (step 3), and a purge process is then performed (step 4). And, TMA is supplied as a second metal precursor source (step 5), a purge process is performed (step 6), and H₂O, O₃ gas or O₂ plasma is supplied as a reaction gas at a wafer temperature of 300 to 600° C. (step 7), a purge process is then performed (step 8). Here, the steps 1 through 4 is defined as “unit cycle (C)” and the steps 5 through 8 is defined as “unit cycle (D)”. The number of times the unit cycle C is performed differs from that of the unit cycle D, so as to obtain the predetermined composition ratio of Hf:Al or Zr:Al. At this time, nitrogen (N₂) and argon (Ar) are used as a purge gas to inhibit a chemical vapor deposition (CVD) reaction from being performed, and so the nano-mixed type amorphous HfAlO layer and ZrAlO layer having an excellent layer quality and a high density are formed through the HfO₂ layer, the ZrO₂ layer and the Al₂O₃ layer having an excellent layer quality.

For example, to form the nano-mixed type HfAlO layer having a composition ratio of Hf:Al of 24:1, a thickness of each of the HfO₂ layer, the Al₂O₃ layer and the ZrO₂ layer from each unit cycle C and each unit cycle D is 0.1 Å to 9.9 Å. At this time, the unit cycle C is repeated 24 times to form the HfO₂ layer of a certain thickness and the unit cycle D is repeated once to form the thin Al₂O₃ layer of a certain thickness, and so the amorphous HfAlO layer in which the HfO₂ layer and the Al₂O₃ layer are nano-mixed with a predetermined composition ratio.

The high dielectric insulating layer 140 consisting of the amorphous HfAlO layer or the ZrAlO layer are nano-mixed and formed by alternately stacking the HfO₂/Al₂O₃ layers or the ZrO₂/Al₂O₃ layers according to the present embodiment. The layer 140 comprises the amorphous HfO₂ layer or the ZrO₂ layer formed through the atomic layer deposition method at a temperature of 400 or 500° C., or at a temperature range of 450 to 500° C. using a precursor selected from materials expressed by the chemical formula 1 to the chemical formula 6 having a high dissolving temperature and a high vapor pressure at a high temperature. As a result, although a subsequent annealing process is performed at a temperature of 700 to 1,000° C., crystallization in the high dielectric insulating layer 140 is less than the high dielectric insulating layer formed at a temperature of approximately 300° C., and so a grain boundary path can be decreased to enhance the CET characteristic and a leakage current characteristic.

On the other hand, the nano-mixed type amorphous HfAlO layer or the ZrAlO layer can be formed by stacking the Al₂O₃/HfO₂ layers or the Al₂O₃/ZrO₂ layers, which are the reversed structures of the HfO₂/Al₂O₃ layers or the ZrO₂/Al₂O₃ layers.

Referring to FIG. 1C, a third insulating layer 150 is formed on the high dielectric insulating layer 140. The third insulating layer 150 is used as an upper oxide layer of the dielectric layer between the floating gate and the control gate in the NAND flash device and as an inter-insulating layer between a lower electrode of a capacitor and an upper electrode of the capacitor in a process for forming the capacitor. The third insulating layer may be formed of a HTO oxide layer. In this case, the third insulating layer is formed with a thickness of 10 to 50 Å through a CVD method (e.g., a LPCVD method). Accordingly, in the NAND flash device consisting of the second insulating layer 130, the high dielectric insulating layer 140 and the third insulating layer 150, a dielectric layer 160 having an OKO structure is formed.

In the high dielectric layer 160 according to the present embodiment, a high dielectric insulating layer 160 may comprise (1) a single amorphous HfO₂ layer or ZrO₂ layer having a high density, (2) a stack layer of amorphous HfO₂/Al₂O₃ layer or ZrO₂/Al₂O₃ layer, or (3) an amorphous HfAlO layer or ZrAlO layer in which HfO₂/Al₂O₃ or ZrO₂/Al₂O₃ are mixed in a nano-mixed manner. The layer 160 is formed through the atomic layer deposition method at a temperature above 400° C. using a precursor selected from materials expressed by the chemical formula 1 to the chemical formula 6 having a high dissolving temperature and a high vapor pressure at a high temperature. The layer 160 is formed between the second and third insulating layers 130 and 150 formed of the HTO oxide layers, and so when an annealing process is subsequently performed at a high temperature, crystallization of the thin layer is reduced to decrease a grain boundary path. Consequently, a CET characteristic and leakage current can be improved and a device having a high reliability can be manufactured on the basis of the above improved characteristics.

Subsequently, a second conductive layer 170 is formed on the third insulating layer 150 of the high dielectric layer 160. The second conductive layer 170 is utilized as a control gate of a NAND flash memory device or an upper electrode of a capacitor, and can be formed of a doped polysilicon layer, a metal layer or a stacked layer of the two. At this time, the second conductive layer 170 can be formed through the CVD method. The second conductive layer may be formed with a thickness of 500 to 2,000 Å through the LPCVD method. On the other hand, to reduce a resistance, a metal silicide layer (not shown) can be formed on the second conductive layer 170.

Then, the metal silicide layer, the second conductive layer 170, the dielectric layer 160 and the first conductive layer 120 are sequentially patterned by a conventional etching process. In the NAND flash device, accordingly, a gate (not shown) comprising of the floating gate (not shown) consisting of the first conductive layer 120 and the control gate (not shown) consisting of the second conductive layer 170 is formed.

On the other hand, the first conductive layer 120 and the second insulating layer 130 or the second conductive layer 170 and the third insulating layer 150 chemically react with each other, and so defects are generated on an interface between the first conductive layer 120 and the second insulating layer 130 and an interface between the second conductive layer 170 and the third insulating layer 150. Due to the defects, a dielectric constant of the high dielectric layer 160 is lowered. To prevent the dielectric constant of the high dielectric layer from being lowered, a plasma nitration treatment can be performed to form a nitride layer (not shown) on a surface of the first conductive layer 120 and a surface of the third insulating layer 150 before the second insulating layer 130 is formed and after the third insulating layer 150 is formed. At this time, the plasma nitration treatment can be carried out using a rapid thermal process (RTP) under a mixed atmosphere of argon gas and N₂ gas at a temperature of 600° C. to 1,000° C.

Then, to remedy damage caused by an etching process for forming the gate, an oxidation process for a side wall can be additionally performed, and so an oxide layer is formed on a side wall of the gate.

FIG. 7 is a graph showing a capacitance equivalent thickness (CET) characteristic and a leakage current characteristic of a high dielectric insulating layer according to the present embodiment.

In FIG. 7, the marks “ [symbol] ” and “ [symbol] ” indicate the high dielectric insulating layer according to the present embodiment, and other marks indicate the high dielectric insulating layer according to the prior arts and are provided for comparing the high dielectric insulating layer of the present embodiment.

Referring to FIG. 7, in the conventional high dielectric insulating layer, a leakage current is large when the CET is low and a leakage current is small when the CET is high. On the other hand, the high dielectric insulating layer according to the present embodiment has a characteristic that the CET is lower and a leakage current is also small. That is, when compared to the prior art layer, the leakage current is lower for a given CET value for the high dielectric layer of the present embodiment. In particular, as shown in the section “A” expressed by a dotted line, in a case where HfAlO having a composition ratio of Hf:Al of 24:1 is formed, a CET is about 112 Å and a leakage current is 5˜6E(−15)A/μm², the above values are the best results with respect to the CET and leakage current characteristics. As described above, it is possible to verify through FIG. 7 that the high dielectric insulating layer formed by using the precursor having a high dissolving temperature and a high vapor pressure at a high temperature according to the present embodiment has superior the CET characteristic and the leakage current characteristic compared with the conventional precursor. In particular, in an aspect of a composition of the thin HfAlO layer or ZrAlO layer, the new composition ratio of 24:1 in which a composition of Hf or Zr is higher than that of Al is obtained, so that a leakage current characteristic can be improved while the CET is lowered.

The present embodiment as described above has one or more of the following advantages. First, by forming the amorphous high dielectric insulating layer having a high density by using a precursor which can be deposited through the atomic layer deposition method at a temperature above 400° C., e.g., a temperature of 450 to 500° C., when a subsequent annealing process is performed, crystallization in the high dielectric insulating layer is reduced to decrease the grain boundary. Accordingly, the capacitance equivalent thickness characteristic and the leakage current characteristic are improved so that it is possible to manufacture a device having a high reliability.

Second, since the high dielectric insulating layer made of HfO₂ or ZrO₂ can be formed through the atomic layer deposition method at a temperature above 400° C. by using the precursor of the, the laminate-type amorphous high dielectric insulating layer in which the HfO₂ layer or the ZrO₂ layer and the Al₂O₃ layer are alternately stacked or the nano-mixed type amorphous high dielectric insulating layer in which HfO₂ layer or the ZrO₂ layer and the Al₂O₃ layer are nano-mixed to increase a density of the high dielectric insulating layer, and so an electrical characteristic of the thin layer can be enhanced.

Third, in a composition of the thin HfAlO layer or ZrAlO layer, the composition of Hf or Zr is extremely higher than that Al (e.g., 24:1) and is obtained by using a new precursor so that the leakage current characteristic can be improved while the CET is lowered.

Fourth, a manufacturing cost can be saved and the electrical characteristic required for the device can be secured through a minimum modification of the process.

For a simplicity of the description, the above description has been described in terms of a high dielectric insulating layer being used in the NAND flash memory device and the insulating layer for the capacitor. However, the high dielectric insulating layer according to the present embodiment is not limited thereto, but may be used as a blocking oxide layer in the flash memory device having a SONOS (silicon-oxide-nitride-oxide-silicon) structure or a MONOS (metal-oxide-nitride-oxide-silicon) structure in which a nitride layer is used as an electron storage layer. In this case, the high dielectric insulating layer is formed on the electron storage layer.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, the method comprising:
forming a high dielectric insulating layer comprising a hafnium oxide (HfO₂) layer or zirconium oxide (ZrO₂) layer or both, the high dielectric insulating layer formed over a semiconductor substrate by using a precursor including Hf, Zr, or both at a temperature of at least 400° C.

2. The method of forming a semiconductor device according to claim 1, wherein the precursor includes one selected from the group consisting of Hf[C₅H₄(CH₃)]₂(CH₃)₂, Hf[C₅H₄(CH₃)]₂(OCH₃)CH₃ and Hf[C₅H₄(CH₂CH₃)][N(CH_{3)(CH}₂CH₃)]₃, wherein the high dielectric insulating layer is formed at a temperature of 450° C. to 500° C.

3. The method of forming a semiconductor device according to claim 1, wherein the precursor includes one selected from the group consisting of Hf[C₅H₄(CH₃)]₂(CH₃)₂, Hf[C₅H₄(CH₃)]₂(OCH₃)CH₃ and Hf[C₅H₄(CH₂CH₃)][N(CH₃)(CH₂CH₃)]₃, wherein the high dielectric insulating layer is formed using the atomic layer deposition method at a temperature of 400° C. to 500° C.

4. The method of forming a semiconductor device according to claim 3, wherein the high dielectric insulating layer is formed to a thickness of 40 Å to 500 Å.

5. The method of forming a semiconductor device according to claim 3, wherein the high dielectric insulating layer has any one of an electron-storage layer, a lower oxide layer of a dielectric layer and a lower electrode of a capacitor formed therebelow.

6. The method of forming a semiconductor device according to claim 3, wherein the high dielectric insulating layer has a lower HTO oxide layer formed therebelow and an upper HTO oxide layer formed thereabove.

7. The method of forming a semiconductor device according to claim 6, further comprising:
performing a plasma-nitrifying treatment before forming the lower HTO oxide layer and after forming the upper HTO oxide layer.

8. The method of claim 1, wherein the high dielectric insulating layer is formed using one or more precursors selected from the group consisting of Zr[C₅H₄(CH₃)]₂(CH₃)₂, Zr[C₅H₄(CH₃)]₂(OCH₃)CH₃ and Zr[C₅H₄(CH₂CH₃)][N(CH₃)(CH₂CH₃)]₃.

9. The method of forming a semiconductor device according to claim 8, wherein the high dielectric insulating layer is formed at a temperature of 450° C. to 500° C.

10. The method of forming a semiconductor device according to claim 8, wherein the high dielectric insulating layer is formed through the atomic layer deposition method at a temperature of 450° C. to 500° C.

11. The method of forming a semiconductor device according to claim 8, wherein the high dielectric insulating layer is formed to a thickness of 40 Å to 500 Å.

12. A method of manufacturing a semiconductor device, the method comprising:
forming a high dielectric insulating layer having a stack of layers by stacking alternatively a hafnium oxide (HfO₂) layer and an aluminum oxide (Al₂O₃) layer over a semiconductor substrate, the hafnium oxide layer being formed by using one or more of precursors selected from Hf[C₅H₄(CH₃)]₂(CH₃)₂, Hf[C₅H₄(CH₃)]₂(OCH₃)CH₃ and Hf[C₅H₄(CH₂CH₃)][N(CH₃)(CH₂CH₃)]₃ at a temperature of at least 400° C.

13. The method of forming a semiconductor device according to claim 12, wherein the high dielectric insulating layer is formed at a temperature of 450° C. to 500° C.

14. The method of forming a semiconductor device according to claim 13, wherein the high dielectric insulating layer is formed through the atomic layer deposition method at a temperature of 400° C. to 500° C.

15. The method of forming a semiconductor device according to claim 14, wherein the high dielectric insulating layer is formed to a thickness of 40 Å to 500 Å.

16. The method of forming a semiconductor device according to claim 12, wherein the hafnium oxide (HfO₂) layer and the aluminum oxide (Al₂O₃) layer are formed to a thickness of 10 Å to 30 Å, respectively.

17. The method of forming a semiconductor device according to claim 12, wherein the aluminum oxide (Al₂O₃) layer is formed through a process utilizing trimethyl aluminum (Al(CH₃)₃) as a precursor.

18. The method of forming a semiconductor device according to claim 12, wherein the aluminum oxide (Al₂O₃) layer is formed at a temperature of 400° C. to 500° C.

19. The method of forming a semiconductor device according to claim 15, wherein the aluminum oxide (Al₂O₃) layer is formed at a temperature of 450° C. to 500° C.

20. A method of manufacturing a semiconductor device, the method comprising:
forming a high dielectric insulating layer having a stack of layers by stacking alternatively a zirconium oxide (ZrO₂) layer and an aluminum oxide (Al₂O₃) layer over a semiconductor substrate, the zirconium oxide layer being formed by using one or more of precursors selected from the group consisting of Zr[C₅H₄(CH₃)]₂(CH₃)₂, Zr[C₅H₄(CH₃)]₂(OCH₃)CH₃ and Zr[C₅H₄(CH₂CH₃)][N(CH₃)(CH₂CH₃)]₃ at a temperature of at least 400° C.

21. The method of forming a semiconductor device according to claim 20, wherein the high dielectric insulating layer is formed at a temperature of 450° C. to 500° C.

22. The method of forming a semiconductor device according to claim 20, wherein the high dielectric insulating layer is formed through the atomic layer deposition method at a temperature of 400° C. to 500° C.

23. The method of forming a semiconductor device according to claim 20, wherein the high dielectric insulating layer is formed with a thickness of 40 Å to 500 Å.

24. The method of forming a semiconductor device according to claim 20, wherein the zirconium oxide (ZrO₂) layer and the aluminum oxide (Al₂O₃) layer are formed to a thickness of 10 Å to 30 Å, respectively

25. The method of forming a semiconductor device according to claim 20, wherein the aluminum oxide (Al₂O₃) layer is formed through a process utilizing trimethyl aluminum (Al(CH₃)₃) as the precursor.

26. The method of forming a semiconductor device according to claim 20, wherein the aluminum oxide (Al₂O₃) layer is formed at a temperature of 400° C. to 500° C.

27. The method of forming a semiconductor device according to claim 20, wherein the aluminum oxide (Al₂O₃) layer is formed at a temperature of 450° C. to 500° C.

28. A method of manufacturing a semiconductor device, the method comprising:
forming a high dielectric insulating layer including a nano-mixed hafnium-aluminum (HfAlO) layer by stacking alternatively a hafnium oxide (HfO₂) layer and an aluminum oxide (Al₂O₃) layer over a semiconductor substrate, the hafnium oxide layer being formed by using one or more of precursors selected from the group consisting of Hf[C₅H₄(CH₃)]₂(CH₃)₂, Hf[C₅H₄(CH₃)]₂(OCH₃)CH₃ and Hf[C₅H₄(CH₂CH₃)][N(CH₃)(CH₂CH₃)]₃ at a temperature of at least 400° C.

29. The method of forming a semiconductor device according to claim 28, wherein the high dielectric insulating layer is formed at a temperature of 450° C. to 500° C.

30. The method of forming a semiconductor device according to claim 28, wherein the high dielectric insulating layer is formed through the atomic layer deposition method at a temperature of 400° C. to 500° C.

31. The method of forming a semiconductor device according to claim 30, wherein the high dielectric insulating layer is formed with a thickness of 40 Å to 500 Å.

32. The method of forming a semiconductor device according to claim 28, wherein the hafnium-aluminum oxide (HfAlO) layer has a composition ratio between hafnium (Hf) and aluminum (Al) of 2:1 to 30:1.

33. The method of forming a semiconductor device according to claim 28, wherein the hafnium-aluminum oxide (HfAlO) layer has a composition ratio between hafnium (Hf) and aluminum (Al) of at least 20:1.

34. The method of forming a semiconductor device according to claim 28, wherein the hafnium oxide (HfO₂) layer and the aluminum oxide (Al₂O₃) layer are formed with a thickness of 0.1 Å to 9.9 Å per a unit cycle, respectively.

35. A method of manufacturing a semiconductor device, the method comprising:
forming a high dielectric insulating layer including a nano-mixed zirconium-aluminum (ZrAlO) layer by stacking alternatively a zirconium oxide (ZrO₂) layer and an aluminum oxide (Al₂O₃) layer over a semiconductor substrate, the nano-mixed zirconium-aluminum layer being formed by using one or more precursors selected from the group consisting of Zr[C₅H₄(CH₃)]₂(CH₃)₂, Zr[C₅H₄(CH₃)]₂(OCH₃)CH₃ and Zr[C₅H₄(CH₂CH₃)][N(CH₃)(CH₂CH₃)]₃ at a temperature of at least 400° C.

36. The method of forming a semiconductor device according to claim 35, wherein the high dielectric insulating layer is formed at a temperature of 450° C. to 500° C.

37. The method of forming a semiconductor device according to claim 35, wherein the high dielectric insulating layer is formed through the atomic layer deposition method at a temperature of 400° C. to 500° C.

38. The method of forming a semiconductor device according to claim 35, wherein the zirconium-aluminum oxide (ZrAlO) layer has a composition ratio between zirconium and aluminum of 2:1 to 30:1, wherein the composition ratio is adjusted through the number of an unit cycle in an atomic layer deposition method.

39. The method of forming a semiconductor device according to claim 35, wherein the zirconium-aluminum oxide (ZrAlO) layer has a composition ratio between zirconium and aluminum of at least 20:1.

40. The method of forming a semiconductor device according to claim 39, wherein the composition ratio is adjusted through the number of an unit cycle in an atomic layer deposition method.

41. The method of forming a semiconductor device according to claim 40, wherein the zirconium oxide (ZrO₂) layer and the aluminum oxide (Al₂O₃) layer are formed with a thickness of 0.1 Å to 9.9 Å per the unit cycle, respectively.

42. A method of manufacturing a semiconductor device, the method comprising:
forming a high dielectric insulating layer comprising a hafnium oxide (HfO₂) layer formed over a semiconductor substrate by using one or more precursors selected from the group consisting of Hf[C₅H₄(CH₃)]₂(CH₃)₂, Hf[C₅H₄(CH₃)]₂(OCH₃)CH₃and Hf[C₅H₄(CH₂CH₃)][N(CH₃)(CH₂CH₃)]₃.

43. The method of forming a semiconductor device according to claim 42, wherein the high dielectric insulating layer is formed at a temperature of at least 400° C.

44. The method of forming a semiconductor device according to claim 42, wherein the high dielectric insulating layer is formed at a temperature of 450° C. to 500° C.

45. A method of manufacturing a semiconductor device, the method comprising:
forming a high dielectric insulating layer comprising a zirconium oxide (ZrO₂) layer formed over a semiconductor substrate by using one or more precursors selected from the group consisting of Zr[C₅H₄(CH₃)]₂(CH₃)₂, Zr[C₅H₄(CH₃)]₂(OCH₃)CH₃ and Zr[C₅H₄(CH₂CH₃)][N(CH₃)(CH₂CH₃)]₃.

46. The method of forming a semiconductor device according to claim 45, wherein the high dielectric insulating layer is formed at a temperature of at least 400° C.

47. The method of forming a semiconductor device according to claim 46, wherein the high dielectric insulating layer is formed at a temperature of 450° C. to 500° C.

48. A method of manufacturing a semiconductor device, the method comprising:
forming a high dielectric insulating layer by stacking alternatively a hafnium oxide (HfO₂) layer and an aluminum oxide (Al₂O₃) layer over a semiconductor substrate, the hafnium oxide layer being formed by using one or more precursors selected from Hf[C₅H₄(CH₃)]₂(CH₃)₂, Hf[C₅H₄(CH₃)]₂(OCH₃)CH₃ and Hf[C₅H₄(CH₂CH₃)][N(CH₃)(CH₂CH₃)]₃.

49. The method of forming a semiconductor device according to claim 48, wherein the high dielectric insulating layer is formed at a temperature of 400° C. to 500° C.

50. The method of forming a semiconductor device according to claim 48, wherein the high dielectric insulating layer is formed at a temperature of 450° C. to 500° C.

51. A method of manufacturing a semiconductor device, the method comprising:
forming a high dielectric insulating layer by stacking alternatively a zirconium oxide (ZrO₂) layer and an aluminum oxide (Al₂O₃) layer over a semiconductor substrate, the zirconium oxide layer being formed by using one or more precursors selected from the group consisting of Zr[C₅H₄(CH₃)]₂(CH₃)₂, Zr[C₅H_{4(CH}₃)]₂(OCH₃)CH₃ and Zr[C₅H₄(CH₂CH₃)][N(CH₃)(CH₂CH₃)]₃.

52. The method of forming a semiconductor device according to claim 51, wherein the high dielectric insulating layer is formed at a temperature of 400° C. to 500° C.

53. The method of forming a semiconductor device according to claim 52, wherein the high dielectric insulating layer is formed at a temperature of 450° C. to 500° C.

54. A method of manufacturing a semiconductor device, the method comprising:
forming a high dielectric insulating layer including a nano-mixed hafnium-aluminum (HfAlO) layer by stacking alternatively a hafnium oxide (HfO₂) layer and an aluminum oxide (Al₂O₃) layer on a semiconductor substrate, the hafnium oxide layer being formed by using one or more precursors selected from the group consisting of Hf[C₅H₄(CH₃)]₂(CH₃)₂, Hf[C₅H₄(CH₃)]₂(OCH₃)CH₃ and Hf[C₅H₄(CH₂CH₃)][N(CH₃)(CH₂CH₃)]₃.

55. The method of forming a semiconductor device according to claim 54, wherein the high dielectric insulating layer is formed at a temperature of 400° C. to 500° C.

56. The method of forming a semiconductor device according to claim 54, wherein the high dielectric insulating layer is formed at a temperature of 450° C. to 500° C.

57. A method of manufacturing a semiconductor device, the method comprising:
forming a high dielectric insulating layer including a nano-mixed zirconium-aluminum (ZrAlO) layer by stacking alternatively a zirconium oxide (ZrO₂) layer and an aluminum oxide (Al₂O₃) layer over a semiconductor substrate, the zirconium oxide layer being formed by using a one or more precursors selected from the group consisting of Zr[C₅H₄(CH₃)]₂(CH₃)₂, Zr[C₅H₄(CH₃)]₂(OCH₃)CH₃ and Zr[C₅H₄(CH₂CH₃)][N(CH₃)(CH₂CH₃)]₃.

58. The method of forming a semiconductor device according to claim 57, wherein the high dielectric insulating layer is formed at a temperature of 400° C. to 500° C.

59. The method of forming a semiconductor device according to claim 57, wherein the high dielectric insulating layer is formed at a temperature of 450° C. to 500° C.
